(19) United States
(12) Patent Application Publication
(10) Pub. No.: US 2026/0182449 A1
(43) Pub. Date: Jun. 25, 2026

(54) SEMICONDUCTOR PACKAGE AND PACKAGE METHOD

(71) Applicant: JCET Group Co., LTD., Jiangyin (CN)

(72) Inventors: Kai LIU, Jiangyin (CN); Yaqin WANG, Jiangyin (CN); Sunyan WANG, Jiangyin (CN)

(21) Appl. No.: 19/412,554

(22) Filed: Dec. 8, 2025

(30) Foreign Application Priority Data
Dec. 24, 2024 (CN) 202411918504.1

(51) Int. Cl. H10W 80/00; H10B 80/00; H10W 40/20; H10W 74/10; H10W 90/22

(52) U.S. Cl. CPC H10W 80/331; H10B 80/00; H10W 40/20; H10W 74/111; H10W 80/011; H10W 90/22

(57) ABSTRACT

A semiconductor package and a package method are provided. The semiconductor package includes: a first carrier board having a plurality of first assembly surfaces and a first surface, where signal exchange ports are provided on the first surface; a plurality of package structures, each corresponding to one of the plurality of first assembly surfaces, where each package structure is welded on its corresponding first assembly surface and electrically connected to the first carrier board, where an end of at least one of the plurality of package structures is exposed and faces away from the first surface of the first carrier board; and a High Bandwidth Memory (HBM) structure welded on and electrically connected to a surface of the end of the at least one of the plurality of package structures that face the first carrier board.

### CROSS-REFERENCE TO RELATED APPLICATIONS

This application claims the benefit of priority to Chinese Application No. 202411918504.1, filed Dec. 24, 2024, which is incorporated herein by reference in its entirety.

### TECHNICAL FIELD

The present disclosure relates to the field of semiconductor manufacturing, and particularly relates to a semiconductor package and a package method.

### BACKGROUND

Today's highly integrated package technology enables compact layout for complex passive components, and package process plays a critical role in improving the performance and cost control of passive components. Existing package technologies include Ball Grid Array (BGA), Chip Scale Package (CSP), Wafer Level Package (WLP), 3D Package, and System in Package (SiP), and etc.

### SUMMARY

The embodiments of the present disclosure provide a semiconductor package and a package method. The semiconductor package includes: a first carrier board including a first surface and a plurality of first assembly surfaces, and signal exchange ports are exposed on the first surface of the first carrier board; a plurality of package structures corresponding one-to-one to the plurality of first assembly surfaces of the first carrier board, welded on the first assembly surfaces of the first carrier board and electrically connected with the first carrier board; the first carrier board exposes a first end of at least one package structure away from the first surface; and a High Bandwidth Memory (HBM) structure welded together with a surface of the first end of the at least one package structure facing the first carrier board, and electrically connected with the at least one package structure.

In some implementations, the package structure includes any one of a chip package structure and a chip.

In some implementations, the plurality of first assembly surfaces include a group of second surface and third surface arranged opposed to each other; and the package structure includes: a first package structure welded on the second surface of the first carrier board and electrically connected with the first carrier board; a second package structure welded on the third surface of the first carrier board and electrically connected with the first carrier board.

In some implementations, the first carrier board exposes the first end of the first package structure away from the first surface and the first end of the second package structure away from the first surface; the first carrier board and the first end of the first package structure, as well as the first end of the second package structure enclose a reserved space; and the HBM structure is located within the reserved space, and is welded together with a surface of the first end of the first package structure facing the first carrier board and a surface of the first end of the second package structure facing the first carrier board, respectively, and is electrically connected with the first package structure and the second package structure, respectively.

In some implementations, the first package structure and the second package structure respectively include: a second carrier board including a second assembly surface; a first chip welded on the second assembly surface of the second carrier board and electrically connected with the second carrier board; a first package molding layer located on the second carrier board and covering the first chip; and the HBM structure is welded together with a surface of the second carrier board of the first package structure exposed by the first carrier board facing the first carrier board and a surface of the second carrier board of the second package structure exposed by the first carrier board facing the first carrier board, respectively, and is electrically connected with the second carrier board of the first package structure and the second carrier board of the second package structure, respectively.

In some implementations, the first carrier board exposes the first end of the first package structure away from the first surface; and the HBM structure is welded on a surface of the first end of the first package structure facing the first carrier board and is electrically connected with the first package structure.

In some implementations, the first package structure includes: a second carrier board including a second assembly surface; a first chip welded on the second assembly surface of the second carrier board and electrically connected with the second carrier board; a package molding layer located on the second carrier board and covering the first chip; the second package structure includes: a third carrier board including a third assembly surface; a second chip welded on the third assembly surface of the third carrier board and electrically connected with the third carrier board; a second package molding layer located on the third carrier board and covering the second chip; and the HBM structure is welded together with a surface of the second carrier board of the first package structure exposed by the first carrier board facing the first carrier board, and is electrically connected with the second carrier board of the first package structure.

In some implementations, the semiconductor package further includes: a first heat dissipation layer located on a surface of the second package structure and the HBM structure facing away from the second carrier board of the first package structure, which is used to conduct heat generated by the second package structure and the HBM structure to the outside.

In some implementations, the HBM structure includes a plurality of memory chips stacked on top of one another along the longitudinal direction, and the plurality of memory chips are electrically connected with each other.

In some implementations, the memory chips include a Dynamic Random Access Memory (DRAM).

In some implementations, the semiconductor package further includes: a first welding interconnection structure located between the first package structure and the second surface of the first carrier board, which is used to weld the first package structure on the second surface of the first carrier board and achieve an electrical connection of the first package structure with the first carrier board; and a second welding interconnection structure located between the second package structure and the third surface of the first carrier board, which is used to weld the second package structure on the third surface of the first carrier board and achieve an electrical connection of the second package structure with the first carrier board.

In some implementations, the first surface is a side surface of the first carrier board, the second surface is a back surface of the first carrier board, and the third surface is a front surface of the first carrier board.

Correspondingly, the embodiment of the present disclosure further provides a package method, which includes: providing a first carrier board including a first surface and a plurality of first assembly surfaces, and signal exchange ports are arranged on the first surface of the first carrier board; providing a plurality of package structures, the plurality of package structures corresponding one-to-one to the plurality of first assembly surfaces; welding the plurality of package structures on the first assembly surfaces of the first carrier board, respectively, and achieving electrical connections between the plurality of package structures and the first carrier board, respectively; welding the plurality of package structures on the first assembly surfaces of the first carrier board, respectively, and after achieving electrical connections between the plurality of package structures and the carrier board, the first carrier board exposing a first end of at least one package structure away from the first surface; providing an HBM structure; and welding the HBM structure together with a surface of the first end of the at least one package structure facing the first carrier board, and achieving electrical connection between the HBM structure and the at least one package structure.

In some implementations, the package structure includes any one of a chip package structure and a chip.

In some implementations, the first assembly surface includes a second surface and a third surface arranged opposed to each other; providing a plurality of package structures includes: providing a first package structure and a second package structure; and welding the plurality of package structures on the first assembly surface of the first carrier board, respectively, and achieving electrical connections between the plurality of package structures and the first carrier board includes: welding the first package structure and the second package structure on the second surface and the third surface of the first carrier board, respectively, and achieving electrical connections between the first package structure and the second package structure with the first carrier board, respectively.

In some implementations, after welding the plurality of package structures on the first assembly surfaces of the first carrier board, respectively, and achieving electrical connections between the plurality of package structures and the first carrier board, the first carrier board exposes the first end of the first package structure away from the first surface and the first end of the second package structure away from the first surface; the first carrier board and the first end of the first package structure, as well as the first end of the second package structure enclose a reserved space; and welding the HBM structure together with a surface of the first end of the at least one package structure facing the first carrier board, and achieving electrical connection between the HBM structure and the at least one package structure includes: welding the HBM structure together with a surface of the first end of the first package structure facing the first carrier board and a surface of the first end of the second package structure facing the first carrier board, respectively, and achieving electrical connections of the HBM structure with the first package structure and the second package structure, respectively.

In some implementations, in the step of providing the first package structure and the second package structure, the first package structure and the second package structure respectively include: a second carrier board including a second assembly surface; a first chip welded on the second assembly surface of the second carrier board and electrically connected with the second carrier board; a first package molding layer located on the second carrier board and covering the first chip; and welding the HBM structure together with a surface of the first end of the first package structure facing the first carrier board and a surface of the first end of the second package structure facing the first carrier board, respectively, and achieving electrical connections of the HBM structure with the first package structure and the second package structure, respectively includes: welding the HBM structure together with a surface of the second carrier board of the first package structure exposed by the first carrier board facing the first carrier board and a surface of the second carrier board of the second package structure exposed by the first carrier board facing the first carrier board, respectively, and achieving electrical connection of the HBM structure with the second carrier board of the first package structure and the second carrier board of the second package structure, respectively.

In some implementations, after welding the first package structure and the second package structure on the second surface and the third surface of the first carrier board, respectively, and achieving electrical connections of the first package structure and the second package structure with the first carrier board, respectively, the first carrier board exposes the first end of the first package structure away from the first surface; and welding the HBM structure together with a surface of the first end of the at least one package structure facing the first carrier board, and achieving electrical connection between the HBM structure and the at least one package structure includes: welding the HBM structure on a surface of the first end of the first package structure facing the first carrier board, and achieving an electrical connection of the HBM structure with the first package structure.

In some implementations, in the step of providing the first package structure and the second package structure, the first package structure includes: a second carrier board including a second assembly surface; a first chip welded on the second assembly surface of the second carrier board and electrically connected with the second carrier board; a first package molding layer located on the second carrier board and covering the first chip; the second package structure includes: a third carrier board including a third assembly surface; a second chip welded on the third assembly surface of the third carrier board and electrically connected with the third carrier board; a second package molding layer located on the third carrier board and covering the second chip; and welding the HBM structure on a surface of the first end of the first package structure facing the first carrier board, and achieving an electrical connection of the HBM structure with the first package structure includes: welding the HBM structure together with a surface of the second carrier board of the first package structure exposed by the first carrier board facing the first carrier board, and achieving electrical connection of the HBM structure with the second carrier board of the first package structure.

In some implementations, the package method further includes: providing a first heat dissipation layer; forming the first heat dissipation layer on a surface of the second package structure and the HBM structure facing away from the second carrier board of the first package structure.

The embodiment of the present disclosure provides a semiconductor package, which includes: a first carrier board including a first surface and a plurality of first assembly surfaces, and signal exchange ports are arranged on the first surface of the first carrier board; package structures corresponding one-to-one to the plurality of first assembly surfaces of the first carrier board, welded on the first assembly surfaces of the first carrier board and electrically connected with the first carrier board; the first carrier board exposes a first end of at least one package structure away from the first surface; and an HBM structure welded together with a surface of the first end of the at least one package structure facing the first carrier board, and electrically connected with the at least one package structure.

### BRIEF DESCRIPTION OF THE DRAWINGS

FIG. 1 is a structural schematic diagram of one embodiment of the semiconductor package provided by the technical solution of the present disclosure;

FIG. 2 is a structural schematic diagram of another embodiment of the semiconductor package provided by the technical solution of the present disclosure;

FIG. 3 is a structural schematic diagram of yet another embodiment of the semiconductor package provided by the technical solution of the present disclosure;

FIGS. 4 to 8 are intermediate structural schematic diagrams of structures formed in each step in one embodiment of the package method provided by the technical solution of the present disclosure;

FIGS. 9 to 11 are intermediate structural schematic diagrams formed in each step in another embodiment of the package method provided by the technical solution of the present disclosure; and

FIGS. 12 to 13 are intermediate structural schematic diagrams formed in each step in yet another embodiment of the package method provided by the technical solution of the present disclosure.

### DETAILED DESCRIPTION

The existing package structure has the problem of high cost and low integration level.

In order to solve the aforementioned technical problems, the embodiment of the present disclosure provides a semiconductor package, which includes: a first carrier board including a first surface and a plurality of first assembly surfaces, and signal exchange ports are exposed on the first surface of the first carrier board; package structures corresponding one-to-one to the plurality of first assembly surfaces of the first carrier board, welded on the first assembly surfaces of the first carrier board and electrically connected with the first carrier board; the first carrier board exposes a first end of at least one package structure away from the first surface; and a High Bandwidth Memory (HBM) structure welded together with a surface of the first end of the at least one package structure facing the first carrier board, and electrically connected with the at least one package structure.

In the semiconductor package provided by the embodiment of the present disclosure, the first carrier board includes a plurality of first assembly surfaces, the first assembly surface is welded with a corresponding package structure, respectively, and compared to the existing methods of welding package structures merely on one surface of the first carrier board, it can improve the integration level of the semiconductor package.

In order to make the above objects, characteristics, and advantages of the embodiments of the present disclosure more obvious and understandable, the specific embodiments of the present disclosure are described in detail below in conjunction with the accompanying drawings.

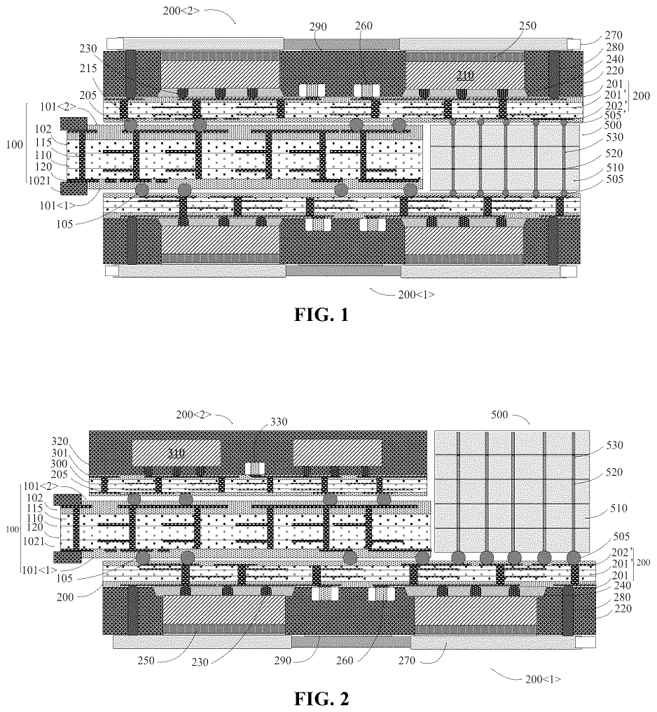

FIG. 1 is a structural schematic diagram of one embodiment of the semiconductor package provided by the technical solution of the present disclosure. Referring to FIG. 1, a semiconductor package includes: a first carrier board 100 including a first surface 102 and first assembly surfaces 101<1>, 101<2>, a signal exchange port 1021 is arranged on the first surface 102 of the first carrier board 100; a first package structure 200<1> welded on the first assembly surface 101<1> of the first carrier board 100 and electrically connected with the first carrier board 100, and the first carrier board 100 exposes a first end (not labeled) of the first package structure 200<1> away from the first surface 102; a second package structure 200<2> welded on the first assembly surface 101<2> of the first carrier board 100 and electrically connected with the first carrier board 100; and an HBM structure 400 welded together with a surface, which faces the first carrier board 100, of the first end of at least one of the first package structure 200<1> and the second package structure 200<2> exposed by the first carrier board 100 away from the first surface 102, and electrically connected with the at least one package structure.

The first carrier board 100 is used to achieve welding of the first package structure 200<1> with the second package structure 200<2>, thereby achieving package integration and electrical integration between the first carrier board 100 with the first package structure 200<1> and the second package structure 200<2>.

In some implementations, the first carrier board 100 has in it conductive lines, the conductive lines are used to supply power or exchange signals for the first package structure 200<1> and the second package structure 200<2>, thereby achieving package integration of the first package structure 200<1> with the second package structure 200<2>. Meanwhile, by arranging the the first package structure 200<1> and the second package structure 200<2> on the first carrier board 100 in an integrated manner, it is conductive to improving the integration level of the semiconductor package.

In the present embodiment, the first carrier board 100 includes a first dielectric layer 110 and a first wiring layer 120 located in the first dielectric layer 110.

The first dielectric layer 110 is used to achieve electrical isolation between the first wiring layers 120, thereby reducing the risk of leakage current between adjacent first wiring layers 120.

As an example, the material of the first dielectric layer 110 includes one or more of silicon oxide, silicon nitride, silicon nitride oxide, and polyimide.

The first wiring layer 120 is used to be electrically connected with the first package structure 200<1> and the second package structure 200<2>, and through the first wiring layer 120, input ports and output ports on the first package structure 200<1> and the second package structure 200<2> can be redistributed, which helps to improve the flexibility of electrical signal connections and helps to reduce the path length of electrical signal transmission, which reduces the transmission delay of electrical signals.

As an example, the material of the first wiring layer 120 is copper. In other embodiments, the material of the wiring layer can also be at least one of aluminum and silver.

In the present embodiment, a first interconnection through-via structure 115 is arranged in the first dielectric layer 110 between adjacent first wiring layers 120. Through the first interconnection through-via structure 115, electrical connections between adjacent first wiring layers 120 can be achieved.

As an example, the material of the first interconnection through-via structure 115 is copper. In other embodiments, the material of the first interconnection through-via structure can also be tungsten, cobalt, or tungsten-cobalt alloy, and etc., which can be configured by those skilled in the art according to actual requirements, and no limitation is imposed herein.

In the present embodiment, the first carrier board 100 includes first assembly surfaces 101<1> and 101<2>. In some implementations, the first assembly surfaces 101<1> and 101<2> are the second surface and the third surface of the first carrier board 100, respectively. Wherein the second surface of the first carrier board 100 is a back surface of the first carrier board 100, and the third surface of the first carrier board 100 is a front surface of the first carrier board 100.

In the present embodiment, the first assembly surface 101<1> of the first carrier board 100 is used to achieve welding with the first package structure 200<1>, the first assembly surface 101<2> of the first carrier board 100 is used to achieve welding with the second package structure 200<2>.

In the present embodiment, the first carrier board 100 further includes a first surface 102. In some implementations, the first surface 102 of the first carrier board 100 is a side surface of the first carrier board 100.

The first surface 102 of the first carrier board 100 is used to achieve signal exchange between the semiconductor package and the outside. In some implementations, a signal exchange port 1021 is exposed on the first surface 102 of the first carrier board 100, the signal exchange port 1021 is used to achieve signal exchange between the first carrier board 100 and the outside, thereby achieving signal exchange between the semiconductor package and the outside. It should be understood that the signal exchange port 1021 may be arranged on the first surface 102 of the first carrier board 100, and it may also be arranged on the end of the first assembly surface of the first carrier board 100 close to the first surface 102.

As an example, the first carrier board 100 includes an organic substrate or a glass substrate having circuits.

Referring again to FIG. 1, in the present embodiment, the first package structure 200<1> and the second package structure 200<2> respectively include: a second carrier board 200 including a second assembly surface 201; a first chip 210 welded on the second assembly surface 201 of the second carrier board 200 and electrically connected with the second carrier board 200; a first package molding layer 220 located on the second carrier board 200 and covering the first chip 210.

The second carrier board 200 is used to provide a process platform for packaging the first chip 210.

In the present embodiment, the second carrier board 200 includes a second dielectric layer 201′ and a second wiring layer 202′ located in the second dielectric layer.

As an example, the material of the second dielectric layer 201′ includes one or more of silicon oxide, silicon nitride, silicon nitride oxide, and polyimide.

The second wiring layer 202′ is used for electrical connection with the first chip 210, through the second wiring layer 202′, the input port and output port on the first chip 210 can be redistributed, thereby helping to improve the flexibility of electrical signal connections, and it is conductive to reducing the path length of electrical signal transmission and decreasing the transmission delay of electrical signals.

The second wiring layer 202′ is also used to electrically connect with the first carrier board 100, thereby achieving electrical connections between the first package structure 200<1> and the second package structure 200<2> with the first carrier board 100.

As an example, the second carrier board 200 may be one of a silicon substrate, a redistribution layer (RDL) substrate, a resin substrate, a Printed Circuit Board (PCB), a ceramic substrate, a glass substrate, or a Flexible Printed Circuit (FPC). As an example, the second carrier board 200 may be a single-layer board or a multi-layer board.

The first chip 210 is used to achieve package integration and electrical integration with the second carrier board 200 to form a corresponding package structure to meet corresponding functional requirements.

In some implementations, the first chip 210 may be manufactured using integrated circuit manufacturing technology. The first chip 210 typically includes devices such as NMOS devices and/or PMOS devices and etc. formed on a semiconductor substrate.

For example, the first chip 210 may be one or more of a System-on-Chip (SoC), a memory chip, an Application-Specific Integrated Circuit (ASIC) chip, a Central Processing Unit (CPU) chip, a Graphics Processing Unit (GPU) chip, and an Field-Programmable Gate Array (FPGA) chip.

According to actual requirements, the number of first chips 210 may be one or more. Wherein in the case where the number of first chips 210 is multiple, the functions of the plurality of first chips 210 are different.

Referring again to FIG. 1, in the present embodiment, the first chip 210 is welded on the second assembly surface 201 of the second carrier board 200. In some implementations, the first package structure 200<1> and the second package structure 200<2> respectively further include: a fifth welding interconnection structure 230 located between the first chip 210 and the second carrier board 200, which is used to weld the first chip 210 on the second assembly surface 201 of the second carrier board 200 and is used to achieve an electrical connection between the first chip 210 and the second carrier board 200.

The fifth welding interconnection structure 230 is used to lead out the electrical properties of the first chip 210 and is used to achieve the arrangement of the first chip 210 on the topmost second wiring layer 202′, which reduces the risk of separation of the first chip 210 and the second wiring layer 202′ from each other. Meanwhile, the fifth welding interconnection structure 230 is also used to achieve an electrical connection between the first chip 210 and the second wiring layer 202′, so that the first chip 210 can be electrically connected with the second carrier board 200 through the fifth welding interconnection structure 230.

In the present embodiment, the fifth welding interconnection structure 230 is a bump.

In some implementations, in the process of forming the first package structure 200<1> and the second package structure 200<2>, the fifth welding interconnection structure 230 is formed using a bump process.

As an example, the material of the fifth welding interconnection structure 230 includes one or more of gold, lead-tin, silver-tin, gold-tin, and copper-tin.

In other embodiments, the back surface of the first chip may also be mounted with the front surface of the second carrier board, and electrical connection with the second carrier board is achieved through leads.

In the present embodiment, the first package structure 200<1> and the second package structure 200<2> respectively further include: a first underfill layer 240 located between the first chip 210 and the second carrier board 200, and also filled the gaps between the fifth welding interconnection structures 230.

The first underfill layer 240 can protect the first chip 210 from external environmental influences, which can reduce the impact of thermal expansion coefficient mismatch between the first chip 210 and the second carrier board 200, and it is possible to redistribute stress and strain to avoid the failure of the fifth welding interconnection structures 230, and it is conductive to improving the reliability of welding between the first chip 210 and the second assembly surface 201 of the second carrier board 200, and thus it is conductive to improving the reliability of the obtained package structure.

As an example, the material of the first underfill layer 240 includes epoxy resin. In other embodiments, the material of the first underfill layer may also be made of other thermosetting materials, which can be selected by those skilled in the art according to actual requirements, and no limitation is imposed herein.

Referring again to FIG. 1, in the present embodiment, the first package structure 200<1> and the second package structure 200<2> further include: a second heat dissipation layer 250 formed on the first chip 210, which is used to conduct heat generated during the operation of the first chip 210 to the outside.

The second heat dissipation layer 250 is used to conduct heat generated during the operation of the first chip 210 to the outside, which can prevent damage to the first chip 210 caused by the accumulation of heat generated during the operation of the first chip 210, thereby providing protection for the first chip 210.

In the present embodiment, the material of the second heat dissipation layer 250 is copper, copper has superior thermal conductivity and can quickly conduct the heat generated by the first chip 210 during operation to the outside world, which is conducive to improving heat dissipation efficiency.

In other embodiments, the heat dissipation layer may also be made of metallic materials or alloy materials suitable for use as heat sinks, such as aluminum, gold, nickel, steel, or stainless steel, and etc.

Referring again to FIG. 1, in the present embodiment, the first package structure 200<1> and the second package structure 200<2> respectively further include: a first passive component 260 located on the second assembly surface 201 of the second carrier board 200 exposed by the first chip 210, which is electrically connected with the second carrier board 200.

The first passive component 260 is a passive device. Passive devices are passive components that exhibit their characteristics without requiring an external power source, which primarily include at least one of resistive devices, inductive devices, and capacitive devices, such as resistors, capacitors, inductors, converters, tapers, matching networks, resonators, filters, mixers, and switches, and etc.

The first passive component 260 may be welded together with the second assembly surface 201 of the second carrier board 200 through bumps, and achieve an electrical connection with the second carrier board 200. In other embodiments, other implementable welding methods may also be used.

The first package molding layer 220 is used to seal the first chip 210 and the first passive component 260 inside it, so that it can serve for sealing the first chip 210 and the first passive component 260, which can reduce the probability of damage, contamination, or oxidation to the first chip 210 and the first passive component 260.

The first package molding layer 220 is made of a molding material, the strength of the molding material is high, which can correspondingly improve the strength of the first package molding layer 220, thereby facilitating the improvement of the overall strength of the package structure.

In the present embodiment, the material of the first package molding layer 220 is epoxy resin. Epoxy resin has the advantages of low shrinkage, good adhesion, good corrosion resistance, superior electrical properties, and low cost, and etc., therefore it is widely used as a package material for electronic devices and integrated circuits.

In other embodiments, the material of the first package molding layer may also be other suitable materials, such as thermosetting materials like polyimide or silicone rubber, and etc.

In the present embodiment, the top surface of the second heat dissipation layer 250 is exposed by the first package molding layer 220, so that it is able to conduct the heat generated by the first chip 210 during operation to the outside quickly, which is conductive to improve heat dissipation efficiency.

Referring again to FIG. 1, in the present embodiment, the first package structure 200<1> and the second package structure 200<2> respectively further include: a second passive component 270 located above the first chip 210 and electrically connected with the second carrier board 200.

The second passive component 270 is located above the first chip 210, i.e., the second passive component 270 and the first chip 210 are arranged stacked on top of one another along the longitudinal direction, and compared to the case where the first chip 210 and the second passive component 270 are arranged side-by-side along the horizontal direction, it can reduce the area occupied by the second passive component 270 on the second carrier board 200 and reduce the volume of the package structure, and correspondingly it helps to improve the integration level of the package structure and contributes to reduction of the cost of the package structure.

In the present embodiment, a second heat dissipation layer 250 is mounted on the first chip 210, and in the case where the first package molding layer 220 exposes the top surface of the second heat dissipation layer 250, the second passive component 270 is located above the first package molding layer 220 and the second heat dissipation layer 250.

As an example, the second passive component 270 is an inductor. In other embodiments, the second passive component may also be at least one of a capacitor, resistor, converter, taper, matching network, resonator, filter, mixer, switch and etc.

Referring again to FIG. 1, in the present embodiment, the first package structure 200<1> and the second package structure 200<2> respectively further include: a conductive pillar 280 located on the second carrier board 200 exposed by the first chip 210, which is used to achieve electrical connection between the second passive component 270 and the second carrier board 200.

In some implementations, one end of the conductive pillar 280 is electrically connected with the second carrier board 200, and the other end of the conductive pillar 280 is electrically connected with the second passive component 270, thereby achieving electrical connection between the second passive component 270 and the second carrier board 200.

In the present embodiment, the material of the conductive pillar 280 is copper. In other embodiments, the material of the conductive pillar may also be metallic materials such as aluminum, tin, silver, and etc.

In the present embodiment, the number of conductive pillars 280 is multiple, and the plurality of conductive pillars 280 are arranged at intervals from each other.

In the present embodiment, the first package molding layer 220 also covers the sidewalls of the conductive pillars 280, thereby reducing the probability of damage, contamination or oxidation to the conductive pillars 280.

Referring again to FIG. 1, in the present embodiment, the first package structure 200<1> and the second package structure 200<2> respectively further include: a first mounting layer 290 located between the second passive component 270 and the first package molding layer 220, which is used to adhere the second passive component 270 on the first package molding layer 220.

The first mounting layer 290 is used to adhere the second passive component 270 on the first package molding layer 220, thereby further improving the fixation strength of the second passive component 270.

In the present embodiment, a second heat dissipation layer 250 is also mounted above the first chip 210, and in the case where the top surface of the second heat dissipation layer 250 is exposed by the first package molding layer 220, the first mounting layer 290 is located between the second passive component 270 and the second heat dissipation layer 250 as well as the first package molding layer 220.

In the present embodiment, the material of the first mounting layer 290 includes one or two of a resin adhesive and a double-sided adhesive film.

Taking the case where the structures of the first package structure and the second package structure are the same as an example, the first package structure and the second package structure in the embodiments of the present disclosure are described above. It should be understood that the first package structure and the second package structure may also be different, and no limitation is imposed herein.

Taking the case where the package structures of the first package structure and the second package structure are formed using ball grid array package process respectively as an example, the first package structure and the second package structure are described above. In other embodiments, the first package structure and the second package structure may also be formed using package processes such as chip-scale package, wafer-level package, 3D package, and system-in-package, respectively, and no limitation is imposed herein.

In other embodiments, besides the fact that the first package structure and the second package structure may be chip package structure, at least one of the first package structure and the second package structure may also be a chip, and chip package structure or chip can also be welded on the remaining side surfaces of the first carrier board, respectively, to further improve the integration level of the formed semiconductor package.

The HBM structure 500 is used to achieve high-speed data transmission between the Central Processing Unit (CPU) and the Graphics Processing Unit (GPU).

In the present embodiment, the HBM structure 500 includes a plurality of memory chips 510 stacked in sequence along the longitudinal direction.

As an example, the memory chip 510 is a Dynamic Random Access Memory (DRAM). In other embodiments, the memory chip may also be other types of memory chips, and no limitation is imposed herein.

In the present embodiment, the HBM structure 500 further includes: a fifth welding interconnection structure 520 located between adjacent memory chips 510 to achieve welding and electrical connection between adjacent memory chips 510.

In the present embodiment, the fifth welding interconnection structure 520 is a solder ball. Correspondingly, the fifth welding interconnection structure 520 is formed using a ball planting process.

In the present embodiment, the material of the solder ball is tin. In other embodiments, other suitable metallic materials or alloy materials may also be used to make the solder ball, and no limitation is imposed herein.

In other embodiments, the fifth welding interconnection structure may also be a micro-bump. In some implementations, the micro-bump includes a first sub-micro-bump located on the assembly surface of the upper-layer memory chip and a second sub-micro-bump located on the assembly surface of the lower-layer memory chip.

In the present embodiment, the HBM structure 500 further includes: a running through through-hole structure 530 which at least partially runs through the memory chip 510 along the longitudinal direction and is electrically connected with the fifth welding interconnection structure 520.

The running through through-hole structure 530 and the fifth welding interconnection structure 520 together serve to achieve electrical connection between adjacent memory chips 510. In some implementations, the running through through-hole structure 530 in the memory chip 510 at the upper-layer and the running through through-hole structure 530 in the memory chip 510 at the lower-layer are electrically connected with the fifth welding interconnection structure 520 located between adjacent memory chips 510, respectively, thereby achieving electrical connection between adjacent memory chips 510.

In the present embodiment, the material of the running through through-hole structure 530 is copper. In other embodiments, the running through through-hole structure may also be of tungsten, cobalt, or tungsten-cobalt alloy, and etc.

Referring again to FIG. 1, the semiconductor package further includes: a first welding interconnection structure 105 located between the first package structure 200<1> and the second surface of the first carrier board 100, which is used to weld the first package structure 200<1> on the second surface of the first carrier board 100 and achieve an electrical connection between the first package structure 200<1> and the first carrier board 100.

As an example, the first welding interconnection structure 105 is a solder ball or a bump. In other embodiments, other implementable methods may also be used for connection and no limitation is imposed herein.

Correspondingly, the first welding interconnection structure 105 is formed using a ball planting process or a bump process.

Referring again to FIG. 1, the semiconductor package further includes: a second welding interconnection structure 205 located between the second package structure 200<2> and the third surface of the second carrier board 200, which is used to weld the second package structure 200<2> on the third surface of the first carrier board 100 and achieve an electrical connection between the second package structure 200<2> and the first carrier board 100.

As an example, the second welding interconnection structure 205 is a solder ball or a bump. As an embodiment, the material of the solder ball includes tin. In other embodiments, other implementable methods may also be used for connection and no limitation is imposed herein.

Correspondingly, the second welding interconnection structure 205 is formed using a ball planting process or a bump process.

In the present embodiment, the first end of the first package structure 200<1> away from the first surface (not labeled) and the first end of the second package structure 200<2> away from the first surface (not labeled) are exposed by the first carrier board 100; furthermore, the first carrier board 100, the first end of the first package structure 200<1> away from the first surface exposed by the first carrier board 100, and the first end of the second package structure 200<2> away from the first surface exposed by the first carrier board 100 enclose a reserved space.

The HBM structure 500 is located within the reserved space, and is welded together with the surface, which faces the first carrier board 100, of the first end of the first package structure 200<1> away from the first surface exposed by the first carrier board 100, and is welded together with the surface, which faces the first carrier board 100, of the first end of the second package structure 200<2> away from the first surface exposed by the first carrier board 100, and is electrically connected with the first package structure 200<1> and the second package structure 200<2>, respectively.

In some implementations, the HBM structure 500 is welded with the surface, which faces the first carrier board 100, of the second carrier board 200 of the first package structure 200<1> exposed by the first carrier board 100, and with the surface, which faces the first carrier board 100, of the second carrier board 200 of the second package structure 200<2> exposed by the first carrier board 100, respectively, and is electrically connected with the second carrier board 200 of the first package structure 200<1> and the second carrier board 200 of the second package structure 200<2>, respectively, thereby achieving the welding and electrical connection of the HBM structure 500 with the first package structure 200<1> and the second package structure 200<2>.

In the present embodiment, the semiconductor package further includes: a third welding interconnection structure 505 located between the HBM structure 500 and the first package structure 200<1>, which is used to achieve welding and electrical connection of the HBM structure 500 with the first package structure 200<1>; and a fourth welding interconnection structure 505′ located between the HBM structure 500 and the second package structure 200<2>, which is used to achieve welding and electrical connection between the HBM structure 500 and the second package structure 200<2>.

The third welding interconnection structure 505 is located between the HBM structure 500 and the second carrier board 200 of the first package structure 200<1>, and is used to achieve welding and electrical connection between the HBM structure 500 and the second carrier board 200 of the first package structure 200<1>, thereby achieving the welding and electrical connection between the HBM structure 500 and the first package structure 200<1>.

The fourth welding interconnection structure 505′ is located between the HBM structure 500 and the second carrier board 200 of the second package structure 200<2>, and is used to achieve welding and electrical connection between the HBM structure 500 and the second carrier board 200 of the second package structure 200<2>, thereby achieving the welding and electrical connection between the HBM structure 500 and the second package structure 200<2>.

In the present embodiment, the third welding interconnection structure 505 and the fourth welding interconnection structure 505′ are solder balls, respectively. In some implementations, the material of the solder balls is tin.

FIG. 2 illustrates a structural schematic diagram of another embodiment of the semiconductor package provided by the technical solution of the present disclosure. The similarities between the present embodiment and the aforementioned embodiment will not be repeated herein. Referring to FIG. 2, the difference between the present embodiment and the aforementioned embodiment lies in: the first carrier board 100 only exposes the first end of the first package structure 200<1> away from the first surface 102; correspondingly, the HBM structure 500 is welded on the surface of the first end of the first package structure 200<1> facing the first carrier board 100 and is electrically connected with the first package structure 200<1>.

In the present embodiment, the HBM structure 500 is welded together with the surface, which faces the first carrier board 100, of the second carrier board 200 of the first package structure 200<1> exposed by the first carrier board 100, and is electrically connected with the second carrier board 200 of the first package structure 200<1>, thereby achieving welding and electrical connection with the first package structure 200<1>.

Referring again to FIG. 2, in the present embodiment, the second package structure 200<2> includes: a third carrier board 300 including a third assembly surface 301; a second chip 310 welded on the third assembly surface 301 of the third carrier board 300 and electrically connected with the third carrier board 300; a second package molding layer 320 located on the third carrier board 300 and covering the second chip 310.

In the present embodiment, the second package structure 200<2> further includes: a third passive component 330 located on the third carrier board 300 exposed by the second chip 310 and electrically connected with the third carrier board 300.

Regarding the third carrier board 300, the second chip 310, the second package molding layer 320, and the third passive component 330 in the second package structure 200<2>, reference may be made to the aforementioned descriptions regarding the second carrier board 200, the first chip 210, the first package molding layer 220, and the first passive component 260, respectively, which will not be repeated herein.

It should be noted that the second chip 310 is different from the first chip 210.

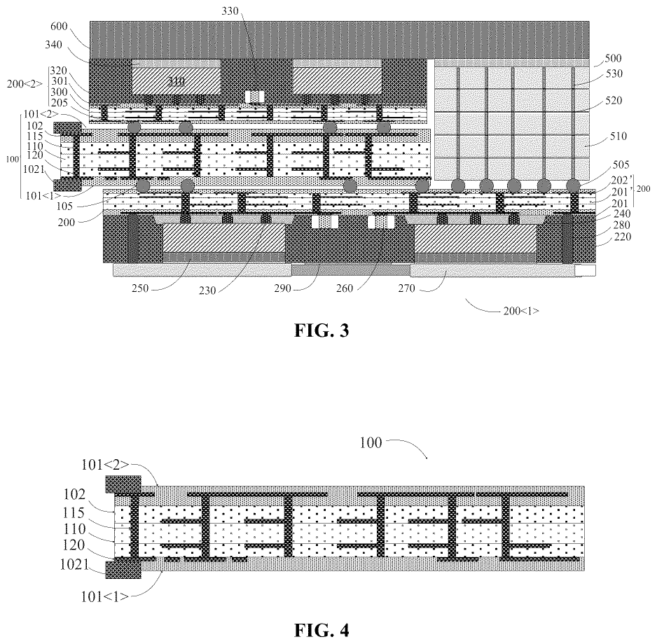

FIG. 3 illustrates a structural schematic diagram of yet another embodiment of the semiconductor package provided by the technical solution of the present disclosure. The similarities between the present embodiment and the aforementioned embodiment will not be repeated herein. Referring to FIG. 3, the difference between the present embodiment and the aforementioned embodiment lies in: the semiconductor package further includes: a first heat dissipation layer 600 located on a surface of the second package structure 200<2> and the HBM structure 500 facing away from the second carrier board 200 of the first package structure 200<1>, which is used to conduct the heat generated by the second package structure 200<2> and the HBM structure 500 to the outside.

The first heat dissipation layer 600 is used to conduct the heat generated by the second package structure 200<2> and the HBM structure 500 to the outside, so that it can avoid the accumulation of heat generated by the second package structure 200<2> and the HBM structure 500 during operation, thereby protecting the second package structure 200<2> and the HBM structure 500.

In the present embodiment, the material of the first heat dissipation layer 600 is copper. Copper has superior thermal conductivity, which helps to quickly conduct the heat generated by the second package structure 200<2> and the HBM structure 500 during operation to the outside world, which is conductive to improving heat dissipation efficiency.

In the present embodiment, the first heat dissipation layer 600 is mounted on a surface of the second package structure 200<2> and the HBM structure 500 facing away from the second carrier board 200 of the first package structure 200<1> using a welding method.

In other embodiments, the first heat dissipation layer may also be formed on the surface of the second package structure and the HBM structure facing away from the second carrier board of the first package structure using other suitable methods.

In the present embodiment, the cross-section of the first heat dissipation layer 600 is rectangular. In other embodiments, the cross-section of the heat sink may also have other suitable shapes according to actual requirements to achieve a tight mounting between the first heat dissipation layer and the surface of the second package structure and the HBM structure facing away from the second carrier board of the first package structure.

The thickness of the first heat dissipation layer 600 may be selected according to requirements of welding performance and heat dissipation performance. As an example, the thickness of the first heat dissipation layer 600 is between 200 μm and 250 μm. Of course, the thickness of the first heat dissipation layer 600 herein is merely an example, and different thicknesses of the first heat dissipation layer 600 may be used for different package structures, and no limitation is imposed herein.

In the present embodiment, the semiconductor package further includes: a second mounting layer 340 located between the first heat dissipation layer 600 and the HBM structure as well as the second chip 310, which is used to adhere to the first heat dissipation layer 600 on the HBM structure 500 and the second chip 310.

The second mounting layer 340 is used to adhere to the first heat dissipation layer 600 on the HBM structure and the second chip 310, thereby achieving a fixed installation between the first heat dissipation layer 600 and the HBM structure 500 as well as the second chip 310.

In the present embodiment, the material of the second mounting layer 340 includes one or two of a resin adhesive and a double-sided adhesive film.

Correspondingly, the present disclosure also provides a package method.

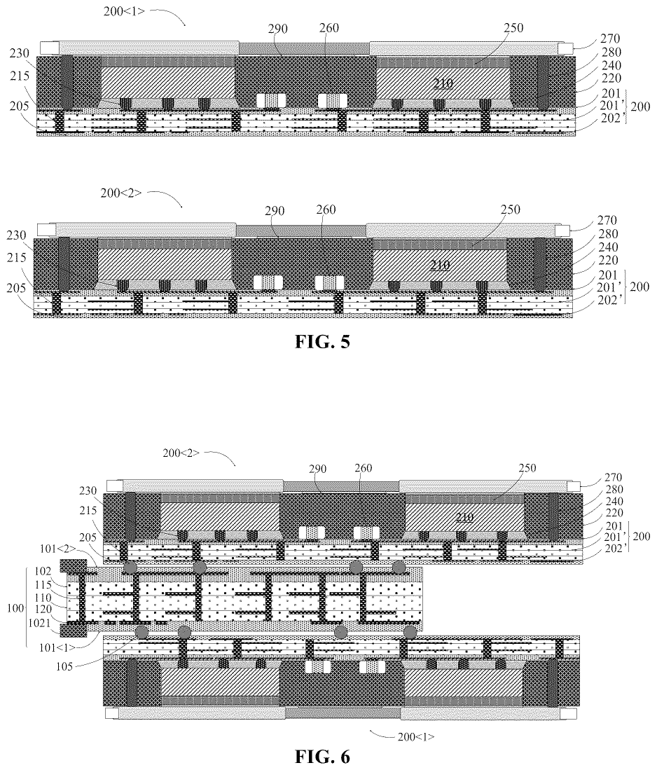

FIGS. 5 to 8 illustrate intermediate structural schematic diagrams of structures formed in each step in one embodiment of the package method provided by the technical solution of the present disclosure.

Referring to FIG. 5, a first carrier board 100 is provided, which includes a first assembly surface 101<1>, 101<2>, and a first surface 102 provided with signal exchange ports 1021.

The first carrier board 100 provides a process platform for forming the semiconductor package.

In some implementations, the first carrier board 100 is used to achieve welding with the first package structure 200<1> and the second package structure 200<2>, thereby achieving package integration and electrical integration between the first carrier board 100 and the first package structure 200<1> as well as the second package structure 200<2>.

In the step of providing the first carrier board 100, the first carrier board 100 has in it conductive lines, the conductive lines are used to supply power or exchange signals for the first package structure 200<1> and the second package structure 200<2>, thereby achieving package integration between the first package structure 200<1> and the second package structure 200<2>. Meanwhile, by arranging the first package structure 200<1> and the second package structure 200<2> on the first carrier board 100 in a integrated manner, it is conductive to improving the integration level of the semiconductor package.

In the present embodiment, the first carrier board 100 includes a first dielectric layer 110 and a first wiring layer 120 located in the first dielectric layer 110.

The first dielectric layer 110 is used to achieve electrical isolation between the first wiring layers 120, thereby reducing the risk of leakage current between adjacent first wiring layers 120.

As an example, the material of the first dielectric layer 110 includes one or more of silicon oxide, silicon nitride, silicon nitride oxide, and polyimide.

The first wiring layer 120 is used to electrically connect with the first package structure 200<1> and the second package structure 200<2>, and through the first wiring layer 120, input ports and output ports on the first package structure 200<1> and the second package structure 200<2> can be redistributed, which helps to improve the flexibility of electrical signal connections and helps to reduce the path length of electrical signal transmission, and reduce the transmission delay of electrical signals.

As an example, the material of the first wiring layer 120 is copper. In other embodiments, the material of the wiring layer can also be at least one of aluminum and silver.

In the present embodiment, a first interconnection through-via structure 115 is arranged in the first dielectric layer 110 between adjacent first wiring layers 120. Through the first interconnection through-via structure 115, electrical connections between adjacent first wiring layers 120 can be achieved.

As an example, the material of the first interconnection through-via structure 115 is copper. In other embodiments, the material of the first interconnection through-via structure can also be tungsten, cobalt, or tungsten-cobalt alloy, and etc., which can be configured by those skilled in the art according to actual requirements, and no limitation is imposed herein.

In the present embodiment, the first carrier board 100 includes first assembly surfaces 101<1> and 101<2>. In some implementations, the first assembly surfaces 101<1> and 101<2> are the second surface and the third surface of the first carrier board 100, respectively. Wherein the second surface of the first carrier board 100 is a back surface of the first carrier board 100, and the third surface of the first carrier board 100 is a front surface of the first carrier board 100.

In the present embodiment, the first assembly surface 101<1> of the first carrier board 100 is used to achieve welding with the first package structure 200<1>, the first assembly surface 101<2> of the first carrier board 100 is used to achieve welding with the second package structure 200<2>.

In the present embodiment, the first carrier board 100 further includes a first surface 102. In some implementations, the first surface 102 of the first carrier board 100 is a side surface of the first carrier board 100.

The first surface 102 of the first carrier board 100 is used to achieve signal exchange between the semiconductor package and the outside. In some implementations, a signal exchange port 1021 is exposed on the first surface 102 of the first carrier board 100, the signal exchange port 1021 is used to achieve signal exchange between the first carrier board 100 and the outside, thereby achieving signal exchange between the semiconductor package and the outside. As an example, the first carrier board 100 includes an organic substrate or a glass substrate having circuits.

Referring to FIG. 5, a first package structure 200<1> and a second package structure 200<2> corresponding one-to-one to the first assembly surfaces 101<1> and 101<2> are provided.

In the present embodiment, the first carrier board 100 further includes the first assembly surfaces 101<1> and 101<2>. Correspondingly, in the step of providing the first package structure 200<1> and the second package structure 200<2>, the first package structure 200<1> and the second package structure 200<2> are provided.

In the present embodiment, in the step of providing the first package structure 200<1> and the second package structure 200<2>, the first package structure 200<1> and the second package structure 200<2> respectively include: a second carrier board 200 including a second assembly surface 201; a first chip 210 welded on the second assembly surface 201 of the second carrier board 200 and electrically connected with the second carrier board 200; a first package molding layer 220 located on the second carrier board 200 and covering the first chip 210.

The second carrier board 200 is used to provide a process platform for packaging the first chip 210.

In the present embodiment, the second carrier board 200 includes a second dielectric layer 201′ and a second wiring layer 202′ located in the second dielectric layer 201′.

As an example, the material of the second dielectric layer 201′ includes one or more of silicon oxide, silicon nitride, silicon nitride oxide, and polyimide.

The second wiring layer 202′ is used for electrical connection with the first chip 210, and through the second wiring layer 202′, the input port and output port on the first chip 210 can be redistributed, thereby helping to improve the flexibility of electrical signal connections, and it is conductive to reducing the path length of electrical signal transmission and decreasing the transmission delay of electrical signals.

The second wiring layer 202′ is also used to be electrically connected with the first carrier board 100, thereby achieving electrical connections of the first package structure 200<1> and the second package structure 200<2> with the first carrier board 100.

In the present embodiment, a second interconnection through-via structure 215 is arranged in the second dielectric layer 201′ between adjacent second wiring layers 202′. Through the second interconnection through-via structure 215, electrical connection between adjacent second wiring layers 202′ can be achieved.

As an example, the material of the second interconnection through-via structure 215 is copper. In other embodiments, the material of the second interconnection through-via structure 215 may also be tungsten, cobalt, or tungsten-cobalt alloy, and etc., which can be configured by those skilled in the art according to actual requirements, and no limitation is imposed herein.

As an example, the second carrier board 200 may be one of a silicon substrate, a RDL substrate, a resin substrate, a PCB, a ceramic substrate, a glass substrate, or a FPC. As an example, the second carrier board 200 may be a single-layer board or a multi-layer board.

The first chip 210 is used to achieve package integration and electrical integration with the second carrier board 200 to form a corresponding package structure to meet corresponding functional requirements.

In some implementations, the first chip 210 may be manufactured using integrated circuit manufacturing technology. The first chip 210 typically includes devices such as NMOS devices and/or PMOS devices and etc. formed on a semiconductor substrate.

For example, the first chip 210 may be one or more of a System-on-Chip (SoC), a memory chip, an Application-Specific Integrated Circuit (ASIC) chip, a Central Processing Unit (CPU) chip, a Graphics Processing Unit (GPU) chip, and an Field-Programmable Gate Array (FPGA) chip.

According to actual requirements, the number of first chips 210 may be one or more. Wherein in the case where the number of first chips 210 is multiple, the functions of the plurality of first chips 210 are different.

In the present embodiment, in the step of providing the first package structure 200<1> and the second package structure 200<2>, the first chip 210 is welded on the second assembly surface 201 of the second carrier board 200. In some implementations, the first package structure 200<1> and the second package structure 200<2> respectively further include: a fifth welding interconnection structure 230 located between the first chip 210 and the second carrier board 200, which is used to weld the first chip 210 on the second assembly surface 201 of the second carrier board 200 and it is used to achieve an electrical connection between the first chip 210 and the second carrier board 200.

The fifth welding interconnection structure 230 is used to lead out the electrical properties of the first chip 210 and achieve arrangement of the first chip 210 on the topmost second wiring layer 202′, which reduces the risk of separation of the first chip 210 and the second wiring layer 202′ from each other. Meanwhile, the fifth welding interconnection structure 230 is also used to achieve an electrical connection between the first chip 210 and the second wiring layer 202′, so that the first chip 210 can be electrically connected with the second carrier board 200 through the fifth welding interconnection structure 230.

In the present embodiment, the fifth welding interconnection structure 230 is a bump.

In some implementations, in the process of forming the first package structure and the second package structure, the fifth welding interconnection structure 230 is formed using a bump process.

As an example, the material of the fifth welding interconnection structure 230 includes one or more of gold, lead-tin, silver-tin, gold-tin, and copper-tin.

In other embodiments, in the step of providing the package structure and the second package structure, the back surface of the first chip is mounted with the front surface of the second carrier board, and electrical connection with the second carrier board is achieved through leads.

In the present embodiment, in the step of providing the first package structure 200<1> and the second package structure 200<2>, the first package structure 200<1> and the second package structure 200<2> respectively further include: a first underfill layer 240 located between the first chip 210 and the second carrier board 200, which also fills the gaps between the fifth welding interconnection structures 230.

The first underfill layer 240 can protect the first chip 210 from external environmental influences, which can reduce the impact of thermal expansion coefficient mismatch between the first chip 210 and the second carrier board 200, and it is possible to redistribute stress and strain to avoid the failure of the fifth welding interconnection structures 230, and it is conductive to improving the reliability of welding between the first chip 210 and the second assembly surface 201 of the second carrier board 200, and thus it is conductive to improving the reliability of the obtained package structure.

As an example, the material of the first underfill layer 240 includes epoxy resin. In other embodiments, the material of the first underfill layer may also be made of other thermosetting materials, which can be selected by those skilled in the art according to actual requirements, and no limitation is imposed herein.

As an example, the first underfill layer 240 is formed using an underfill process. In other embodiments, the first underfill layer may also be formed using other processes, and no limitation is imposed herein.

In the present embodiment, in the step of providing the first package structure 200<1> and the second package structure 200<2>, the first package structure 200<1> and the second package structure 200<2> further include: a second heat dissipation layer 250 formed on the first chip 210, which is used to conduct heat generated during the operation of the first chip 210 to the outside.

The second heat dissipation layer 250 is used to conduct heat generated during the operation of the first chip 210 to the outside, thereby preventing damage to the first chip 210 caused by the accumulation of heat generated during the operation of the first chip 210, thus providing protection for the first chip 210.

In the present embodiment, the material of the second heat dissipation layer 250 is copper, copper has superior thermal conductivity and can quickly conduct the heat generated by the first chip 210 during operation to the outside world, which is conducive to improving heat dissipation efficiency.

In other embodiments, the heat dissipation layer may also be made of metallic materials or alloy materials suitable for use as heat sinks, such as aluminum, gold, nickel, steel, or stainless steel, and etc.

In the present embodiment, in the step of providing the first package structure 200<1> and the second package structure 200<2>, the first package structure 200<1> and the second package structure 200<2> respectively further include: a first passive component 260 located on the second assembly surface 201 of the second carrier board 200 exposed by the first chip 210 and electrically connected with the second carrier board 200.

The first passive component 260 is a passive device. Passive devices are passive components that exhibit their characteristics without requiring an external power source, which primarily include at least one of resistive devices, inductive devices, and capacitive devices, such as resistors, capacitors, inductors, converters, tapers, matching networks, resonators, filters, mixers, switches, and etc.

The first passive component 260 may be welded together with the second assembly surface 201 of the second carrier board 200 through bumps, and achieve an electrical connection with the second carrier board 200. In other embodiments, other implementable methods may also be used for welding.

The first package molding layer 220 is used to seal, inside it, the first chip 210 and the first passive component 260, so that it can serve for sealing the first chip 210 and the first passive component 260, which can reduce the probability of damage, contamination or oxidation to the first chip 210 and the first passive component 260.

The first package molding layer 220 is made of a molding material, the strength of the molding material is high, which can correspondingly improve the strength of the first package molding layer 220, thereby facilitating the improvement of the overall strength of the package structure.

In the present embodiment, the material of the first package molding layer 220 is epoxy resin. Epoxy resin has the advantages of low shrinkage, good adhesion, good corrosion resistance, superior electrical properties, and low cost, and etc., therefore it is widely used as a package material for electronic devices and integrated circuits.

In other embodiments, the material of the first package molding layer may also be other suitable materials, such as thermosetting materials like polyimide or silicone rubber, and etc.

In the present embodiment, the top surface of the second heat dissipation layer 250 is exposed by the first package molding layer 220, so that it is able to conduct the heat generated by the first chip 210 during operation to the outside quickly, which is conductive to improving heat dissipation efficiency.

In the present embodiment, in the step of providing of the first package structure 200<1> and the second package structure 200<2>, the first package structure 200<1> and the second package structure 200<2> respectively further include: a second passive component 270 located above the first chip 210 and electrically connected with the second carrier board 200.

The second passive component 270 is located above the first chip 210, i.e., the second passive component 270 and the first chip 210 are arranged stacked on top of one another along the longitudinal direction, and compared to the case where the first chip 210 and the second passive component 270 are arranged side-by-side along the horizontal direction, it can reduce the area occupied by the second passive component 270 on the second carrier board 200 and reduce the volume of the package structure, and correspondingly it helps to improve the integration level of the package structure and contributes to reduction of the cost of the package structure.

In the present embodiment, a second heat dissipation layer 250 is mounted on the first chip 210, and in the case where the first package molding layer 220 exposes the top surface of the second heat dissipation layer 250, the second passive component 270 is located above the first package molding layer 220 and the second heat dissipation layer 250.

As an example, the second passive component 270 is an inductor. In other embodiments, the second passive component may also be at least one of a capacitor, resistor, converter, taper, matching network, resonator, filter, mixer, switch and etc.

In the present embodiment, in the step of providing the first package structure 200<1> and the second package structure 200<2>, the first package structure 200<1> and the second package structure 200<2> respectively further include: a conductive pillar 280 located on the second carrier board 200 exposed by the first chip 210, which is used to achieve electrical connection between the second passive component 270 and the second carrier board 200.

In some implementations, one end of the conductive pillar 280 is electrically connected with the second carrier board 200, and the other end of the conductive pillar 280 is electrically connected with the second passive component 270, thereby achieving electrical connection between the second passive component 270 and the second carrier board 200.

In the present embodiment, the material of the conductive pillar 280 is copper. In other embodiments, the material of the conductive pillar may also be metallic materials such as aluminum, tin, silver, and etc.

In the present embodiment, the number of conductive pillars 280 is multiple, and the plurality of conductive pillars 280 are arranged at intervals from each other.

In the present embodiment, the first package molding layer 220 also covers the sidewalls of the conductive pillars 280, thereby reducing the probability of damage, contamination, or oxidation to the conductive pillars 280.

In the present embodiment, in the step of providing the first package structure 200<1> and the second package structure 200<2>, the first package structure 200<1> and the second package structure 200<2> respectively further include: a first mounting layer 290 located between the second passive component 270 and the first package molding layer 220, which is used to adhere the second passive component 270 on the first package molding layer 220.

The first mounting layer 290 is used to adhere the second passive component 270 on the first package molding layer 220, thereby further improving the fixation strength of the second passive component 270.

In the present embodiment, a second heat dissipation layer 250 is also arranged above the first chip 210, and in the case where the top surface of the second heat dissipation layer 250 is exposed by the first package molding layer 220, the first mounting layer 290 is located between the second passive component 270 and the second heat dissipation layer 250 as well as the first package molding layer 220.

In the present embodiment, the material of the first mounting layer 290 includes one or two of a resin adhesive and a double-sided adhesive film.

Taking the case where the structures of the first package structure and the second package structure are the same as an example, the first package structure and the second package structure in the embodiments of the present disclosure are described above. It should be understood that the first package structure and the second package structure may also be different, and no limitation is imposed herein.

Taking the case where the package structures of the first package structure and the second package structure are formed using ball grid array package process respectively as an example, the first package structure and the second package structure are described above. In other embodiments, the first package structure and the second package structure may also be formed using package processes such as chip-scale package, wafer-level package, 3D package, and system-in-package, respectively, and no limitation is imposed herein.

In other embodiments, besides the fact that the first package structure and the second package structure may be chip package structure, at least one of the first package structure and the second package structure may also be a chip, and chip package structure or chip can also be welded on the remaining side surfaces of the first carrier board, respectively, to further improve the integration level of the formed semiconductor package.

Referring to FIG. 6, the first package structure 200<1> is welded on the second surface of the first carrier board 100, the second package structure 200<2> is welded on the third surface of the first carrier board 100, and electrical connections between the first package structure 200<1> as well as the second package structure 200<2> and the first carrier board 100 are achieved, respectively.

In the present embodiment, the first assembly surfaces 101<1> and 101<2> of the first carrier board 100 include the second surface and the third surface of the first carrier board 100, the first package structure 200<1> and the second package structure 200<2> include the first package structure 200<1> and the second package structure 200<2>.

Correspondingly, the step of welding the first package structure 200<1> and the second package structure 200<2> on the first assembly surface 101<1> and 101<2> of the first carrier board 100, respectively, and achieving the electrical connections between the first package structure 200<1> and the second package structure 200<2> with the first carrier board 100 includes: welding the first package structure 200<1> on the second surface of the first carrier board 100, welding the second package structure 200<2> on the third surface of the first carrier board 100, and achieving electrical connections between the first package structure 200<1> as well as the second package structure 200<2> and the first carrier board 100, respectively.

In the present embodiment, in the step of welding the first package structure 200<1> on the second surface of the first carrier board 100 and achieving an electrical connection between the first package structure 200<1> and the first carrier board 100 includes: arranging a first welding interconnection structure 105 between the second carrier board 200 of the first package structure 200<1> and the first carrier board 100; welding the first package structure 200<1> on the second surface of the first carrier board 100 through the first welding interconnection structure 105 and achieving an electrical connection between the first package structure 200<1> and the first carrier board 100.

Wherein the step of arranging the first welding interconnection structure 105 between the second carrier board 200 of the first package structure 200<1> and the first carrier board 100 includes: forming the first welding interconnection structure 105 on a surface of the second carrier board 200 of the first package structure 200<1> facing the second surface of the first carrier board 100, or forming the first welding interconnection structure 105 on the second surface of the first carrier board 100, or forming a first sub-welding interconnection structure on a surface of the second carrier board 200 of the first package structure 200<1> facing the second surface of the first carrier board 100, and forming a second sub-welding interconnection structure on the second surface of the first carrier board 100, the first sub-welding interconnection structure and the second sub-welding interconnection structure constitute the first welding interconnection structure 105.

The step of welding the second package structure 200<2> on the third surface of the first carrier board 100 and achieving an electrical connection between the second package structure 200<2> and the first carrier board 100 includes: arranging a second welding interconnection structure 205 between the second carrier board 200 of the second package structure 200<2> and the first carrier board 100; welding the second package structure 200<2> on the third surface of the first carrier board 100 through the second welding interconnection structure 205 and achieving an electrical connection between the second package structure 200<2> and the first carrier board 100.

Wherein the step of arranging the second welding interconnection structure 205 between the second carrier board 200 of the second package structure 200<2> and the first carrier board 100 includes: forming the second welding interconnection structure 205 on a surface of the second carrier board 200 of the second package structure 200<2> facing the third surface of the first carrier board 100, or forming the second welding interconnection structure 205 on the third surface of the first carrier board 100, or forming a third sub-welding interconnection structure on a surface of the second carrier board 200 of the second package structure 200<2> facing the third surface of the first carrier board 100, and forming a fourth sub-welding interconnection structure on the third surface of the first carrier board 100, the third sub-welding interconnection structure and the fourth sub-welding interconnection structure constitute the second welding interconnection structure 205.

In the present embodiment, the first welding interconnection structure 105 and the second welding interconnection structure 205 are respectively bumps. In some implementations, the material of the first welding interconnection structure 105 and the second welding interconnection structure 205 is tin.

As an example, the first welding interconnection structure 105 and the second welding interconnection structure 205 are controlled collapse connections respectively. Controlled collapse connections have excellent electrical performance and thermal characteristics, and are also suitable for mass production, and conductive to reducing the size and weight of package structures.

In the present embodiment, the first welding interconnection structure 105 and the second welding interconnection structure 205 are formed using a bump process.

In the present embodiment, after the first package structure 200<1> is welded on the second surface of the first carrier board 100, and the second package structure 200<2> is welded on the third surface of the first carrier board 100, and electrical connections between the first package structure 200<1> and the second package structure 200<2> with the first carrier board 100 are achieved respectively, the first carrier board 100 exposes the first end of the first package structure 200<1> away from the first surface 102.

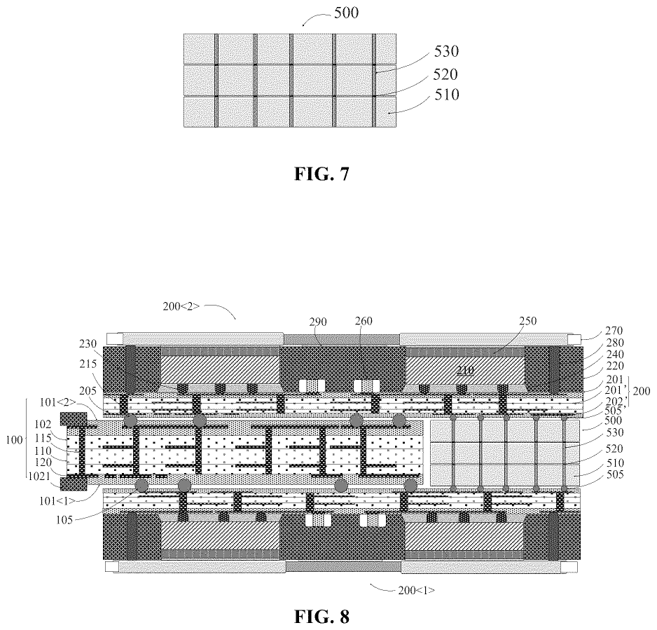

Referring to FIG. 7, an HBM structure 500 is provided.

The HBM structure 500 is used to achieve high-speed data transmission between the CPU and the GPU.

In the present embodiment, in the step of providing the HBM structure 500, the HBM structure 500 includes a plurality of memory chips 510 stacked in sequence along the longitudinal direction.

As an example, the memory chip 510 is a Dynamic Random Access Memory (DRAM). In other embodiments, the memory chip may also be other types of memory chips, and no limitation is imposed herein.

In the present embodiment, in the step of providing the HBM structure 500, the HBM structure 500 further includes: a fifth welding interconnection structure 520 located between adjacent memory chips 510 to achieve welding and electrical connection between adjacent memory chips 510.

In the present embodiment, the fifth welding interconnection structure 520 is a solder ball. Correspondingly, the fifth welding interconnection structure 520 is formed using a ball planting process.

In the present embodiment, the material of the solder ball is tin. In other embodiments, other suitable metallic materials or alloy materials may also be used to make the solder ball, and no limitation is imposed herein.

In other embodiments, the fifth welding interconnection structure may also be a micro-bump. In some implementations, adjacent memory chips include an upper-layer memory chip and a lower-layer memory chip, and correspondingly, the micro-bump includes a first sub-micro-bump located on the assembly surface of the upper-layer memory chip and a second sub-micro-bump located on the assembly surface of the lower-layer memory chip.

In the present embodiment, in the step of providing the HBM structure 500, the HBM structure 500 further includes: a running through through-hole structure 530 which at least runs through partial thickness of the memory chip 510 along the longitudinal direction and is electrically connected with the fifth welding interconnection structure 520.

The running through through-hole structure 530 and the fifth welding interconnection structure 520 together serve to achieve electrical connection between adjacent memory chips 510. In some implementations, the running through through-hole structure 530 in the memory chip 510 at the upper-layer and the running through through-hole structure 530 in the memory chip 510 at the lower-layer are electrically connected with the fifth welding interconnection structure 520 located between adjacent memory chips 510, respectively, thereby achieving electrical connection between adjacent memory chips 510.

In the present embodiment, the material of the running through through-hole structure 530 is copper. In other embodiments, the running through through-hole structure may also be of tungsten, cobalt, or tungsten-cobalt alloy, and etc.

Referring to FIG. 8, the HBM structure 500 is welded together with the surface of the first end of the first package structure 200<1> facing the first carrier board 100 and the surface of the first end of the second package structure 200<2> facing the first carrier board 100, respectively, and achieves electrical connections between the HBM structure 500 and the first package structure 200<1> as well as the second package structure 200<2>.

In the present embodiment, after the first package structure 200<1> is welded on the second surface of the first carrier board 100, and the second package structure 200<2> is welded on the third surface of the first carrier board 100, and electrical connections of the first package structure 200<1> and the second package structure 200<2> with the first carrier board 100 are achieved respectively, the first carrier board 100 exposes the first end of the first package structure 200<1> away from the first surface (not labeled) and the first end of the second package structure 200<2> away from the first surface (not labeled), and furthermore, the first carrier board 100, the first end of the first package structure 200<1> away from the first surface exposed by the first carrier board 100 and the first end of the second package structure 200<2> away from the first surface exposed by the first carrier board 100 enclose a reserved space.

The HBM structure 500 is welded together with the surface of the first end of the first package structure 200<1> facing the first carrier board 100 and the surface of the first end of the second package structure 200<2> facing the first carrier board 100, respectively, thereby arranging the HBM structure 500 within the reserved space.

In the present embodiment, the step of welding the HBM structure 500 together with the surface of the first end of the first package structure 200<1> facing the first carrier board 100 and the surface of the first end of the second package structure 200<2> facing the first carrier board 100, respectively, and achieving electrical connections of the HBM structure 500 with the first package structure 200<1> and the second package structure 200<2> includes: welding the HBM structure 500 together with the surface of the second carrier board 200 of the first package structure 200<1> exposed by the first carrier board 100 facing the first carrier board 100, and the surface of the second carrier board 200 of the second package structure 200<2> exposed by the first carrier board 100 facing the first carrier board 100, and achieving electrical connections of the HBM structure 500 with the second carrier board 200 of the first package structure 200<1> and the second carrier board 200 of the second package structure 200<2>, respectively.

In the present embodiment, a third welding interconnection structure 505 is formed on the surface of the second carrier board 200 of the first package structure 200<1> facing the first carrier board 100, which is exposed by the HBM structure 500 or the first carrier board 100; the HBM structure 500 is welded together with the surface of the second carrier board 200 of the first package structure 200<1> exposed by the first carrier board 100 facing the first carrier board 100 through the third welding interconnection structure 505, and an electrical connection between the HBM structure 500 and the second carrier board 200 of the first package structure 200<1> exposed by the first carrier board 100 is achieved.

In the present embodiment, a fourth welding interconnection structure 505′ is formed on the surface of the second carrier board 200 of the second package structure 200<2> facing the first carrier board 100, which is exposed by the HBM structure 500 or the first carrier board 100; the HBM structure 500 is welded together with the surface of the second carrier board 200 of the second package structure 200<2> exposed by the first carrier board 100 facing the first carrier board 100 through the fourth welding interconnection structure 505′, and an electrical connection between the HBM structure 500 and the second carrier board 200 of the second package structure 200<2> exposed by the first carrier board 100 is achieved.

In the present embodiment, the third welding interconnection structure 505 and the fourth welding interconnection structure 505′ are solder balls, respectively. In some implementations, the material of the bumps is tin.

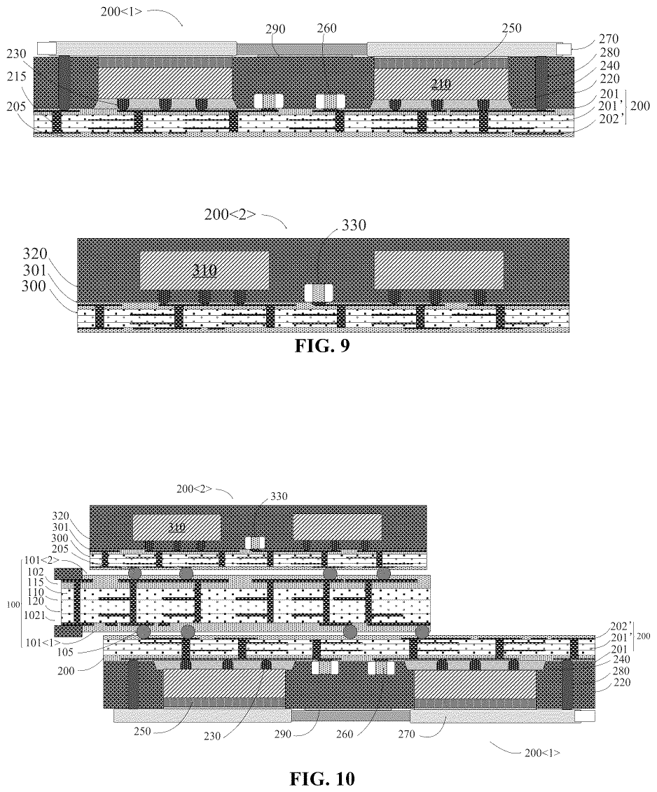

FIGS. 9 to 11 are intermediate structural schematic diagrams formed in each step in another embodiment of the package method provided by the technical solution of the present disclosure. The similarities between the present embodiment and the aforementioned embodiment will not be repeated herein. The difference between the present embodiment and the aforementioned embodiment lies in:

Referring to FIG. 9, in the step of providing the first package structure 200<1> and the second package structure 200<2>, the second package structure 200<2> includes: a third carrier board 300 including a third assembly surface 301; a second chip 310 welded on the third assembly surface 301 of the third carrier board 300 and electrically connected with the third carrier board 300; and a second package molding layer 320 located on the third carrier board 300 and covering the second chip 310.

In the present embodiment, in the step of providing the first package structure 200<1> and the second package structure 200<2>, the second package structure 200<2> further includes: a third passive component 330 located on the third assembly surface 301 of the third carrier board 300 exposed by the second chip and electrically connected with the third carrier board 300.

Regarding the third carrier board 300, the second chip 310, the second package molding layer 320, and the third passive component 330 in the second package structure 200<2>, reference may be made to the aforementioned descriptions regarding the second carrier board 200, the first chip 210, the first package molding layer 220, and the first passive component 260, respectively, which will not be repeated herein.

It should be noted that the second chip 310 is different from the first chip 210.

Referring to FIG. 10, the first package structure 200<1> is welded on the second surface of the first carrier board 100, and the second package structure 200<2> is welded on the third surface of the first carrier board 100, and electrical connections of the first package structure 200<1> and the second package structure 200<2> with the first carrier board 100 are achieved.

In the present embodiment, after welding the first package structure 200<1> on the second surface of the first carrier board 100 and welding the second package structure 200<2> on the third surface of the first carrier board 100, and achieving electrical connections of the first package structure 200<1> and the second package structure 200<2> with the first carrier board 100, the first carrier board 100 exposes the first end of the first package structure 200<1> away from the first surface 101, thereby providing space for subsequently welding the HBM structure 500 together with the first end of the first package structure 200<1> away from the first surface 101.

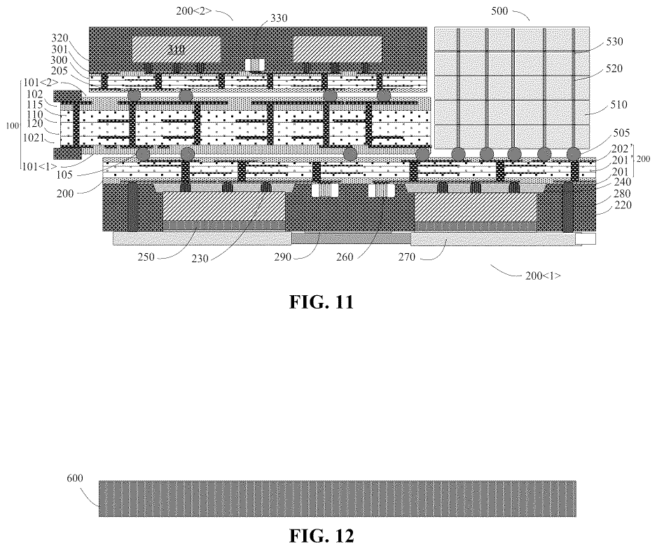

Referring to FIG. 11, after providing the HBM structure 500, the HBM structure 500 is welded together with the first end of the first package structure 200<1> away from the first surface 101, and an electrical connection between the HBM structure 500 and the first package structure 200<1> is achieved.

In the present embodiment, the fact that the HBM structure 500 is welded together with the first end of the first package structure 200<1> away from the first surface 101 and an electrical connection of the HBM structure 500 and the first package structure 200<1> is achieved refers to welding and electrically connecting the HBM structure 500 together with the first end of the first package structure 200<1> away from the first surface 101, which is exposed by the first carrier board 100.

In some implementations, the HBM structure 500 is welded together with the surface of the second carrier board 200 of the first package structure 200<1> exposed by the first carrier board 100 facing the first carrier board 100, and is electrically connected with the second carrier board 200 of the first package structure 200<1>, thereby achieving welding and electrical connection with the first package structure 200<1>.

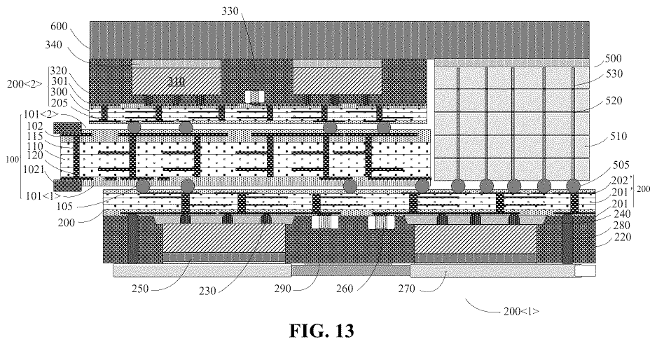

FIGS. 12 to 13 are intermediate structural schematic diagrams formed in each step in yet another embodiment of the package method provided by the technical solution of the present disclosure. The similarities between the present embodiment and the aforementioned embodiment will not be repeated herein. The difference between the present embodiment and the aforementioned embodiment lies in:

Referring to FIG. 12, a first heat dissipation layer 600 is provided.

The first heat dissipation layer 600 is used to conduct the heat generated by the second package structure 200<2> and the HBM structure 500 to the outside, so that it can avoid the accumulation of heat generated by the second package structure 200<2> and the HBM structure 500 during operation, which in turn protects the second package structure 200<2> and the HBM structure.

In the present embodiment, the material of the first heat dissipation layer 600 is copper. Copper has superior thermal conductivity, which helps to quickly conduct the heat generated by the second package structure 200<2> and the HBM structure 500 during operation to the outside world, which is conductive to improving heat dissipation efficiency.

In the present embodiment, the cross-section of the first heat dissipation layer 600 is rectangular. In other embodiments, the cross-section of the heat sink may also have other suitable shapes according to actual requirements to achieve a tight mounting between the first heat dissipation layer and the surface of the second package structure and the HBM structure facing away from the second carrier board of the first package structure.

The thickness of the first heat dissipation layer 600 may be selected according to requirements of welding performance and heat dissipation performance. As an example, the thickness of the first heat dissipation layer 600 is between 200 μm and 250 μm. Of course, the thickness of the first heat dissipation layer 600 herein is merely an example, and different thicknesses of the first heat dissipation layer 600 may be used for different package structures, and no limitation is imposed herein.

Referring to FIG. 13, after welding the HBM structure 500 together with the first end of the first package structure 200<1> away from the first surface 101, and achieving electrical connection between the HBM structure 500 and the first package structure 200<1>, the first heat dissipation layer 600 is formed on the surface of the second package structure 200<2> and the HBM structure 500 facing away from the second carrier board 200 of the first package structure 200<1>.

In the present embodiment, the first heat dissipation layer 600 be mounted on the surface of the second package structure 200<2> and the HBM structure 500 facing away from the second carrier board 200 of the first package structure 200<1> using a welding method.

In other embodiments, the first heat dissipation layer may also be formed on the surface of the second package structure and the HBM structure facing away from the second carrier board of the first package structure using other suitable methods.

The above implementations of the present disclosure are combinations of components and characteristics of the disclosure. Unless otherwise mentioned, components or characteristics may be considered optional. Each components or characteristics may be implemented without combination with other components or characteristics. Additionally, implementations of the present disclosure may be constructed by combining a part of components and/or characteristics. The sequence of operations described in implementations of the disclosure may be rearranged. Some constructions of any implementation may be included in another implementation and may be substituted by corresponding constructions of another implementation. It is obvious to those skilled in the art that the claims that do not have a clear reference relationship with each other in the appended claims may be combined to form implementations of the present disclosure, or may be included as new claims in modifications after submitting the present disclosure.

The above description of the disclosed embodiments enables those skilled in the art to achieve or use the present disclosure. Various modifications to these embodiments will be apparent to those skilled in the art, and the general principles defined herein may be implemented in other embodiments without departing from the spirit or scope of the present disclosure. Therefore, the present disclosure will not be limited to the embodiments shown herein, but will be within the widest scope consistent with the principles and novel characteristics disclosed herein.

Although the present disclosure is disclosed as above, the present disclosure is not limited to this. Any skilled in the art may also make various changes and modifications without departing from the spirit and scope of the present disclosure, therefore the scope of protection of the present disclosure should be based on the scope defined by the claims.

What is claimed is:

1. A semiconductor package, comprising:
a first carrier board having a plurality of first assembly surfaces and a first surface, wherein signal exchange ports are provided on the first surface;
a plurality of package structures, each corresponding to one of the plurality of first assembly surfaces, wherein each package structure is welded on its corresponding first assembly surface and electrically connected to the first carrier board, wherein an end of at least one of the plurality of package structures is exposed and faces away from the first surface of the first carrier board; and
a High Bandwidth Memory (HBM) structure welded on and electrically connected to the end of the at least one of the plurality of package structures that face the first carrier board.

2. The semiconductor package according to claim 1, wherein each of the plurality of package structures comprises a chip or a chip package structure.

3. The semiconductor package according to claim 2, wherein:
the plurality of first assembly surfaces comprise a second surface and a third surface opposing to the second surface; and
the plurality of package structures comprise:
a first package structure welded on the second surface of the first carrier board; and
a second package structure welded on the third surface of the first carrier board, wherein the first package structure and the second package structure are electrically connected to the first carrier board.

4. The semiconductor package according to claim 3, wherein:
the first carrier board is configured such that a first end of the first package structure and a second end of the second package structure are exposed and face away from the first surface, and such that the first carrier board, the first end of the first package structure, and the second end of the second package structure enclose a reserved space; and
the HBM structure is disposed within the reserved space and is welded on and electrically connected to the first end of the first package structure and the second end of the second package structure that face the first carrier board, respectively.

5. The semiconductor package according to claim 4, wherein:
each of the first package structure and the second package structure comprises:
a second carrier board comprising a second assembly surface;
a first chip welded on and electrically connected to the second assembly surface of the second carrier board; and
a first package molding layer on the second carrier board and covering the first chip; and
the HBM structure is welded on and electrically connected to the respective second carrier board of the first package structure and that of the second package structure.

6. The semiconductor package according to claim 4, wherein:
the first carrier board exposes the first end of the first package structure facing away from the first surface; and
the HBM structure is welded on and electrically connected to the first end of the first package structure that faces the first carrier board.

7. The semiconductor package according to claim 6, wherein:
the first package structure comprises:
a second carrier board comprising a second assembly surface;
a first chip welded on and electrically connected to the second assembly surface of the second carrier board; and
a package molding layer on the second carrier board and covering the first chip;
the second package structure comprises:
a third carrier board comprising a third assembly surface;
a second chip welded on and electrically connected to the third assembly surface of the third carrier board; and
a second package molding layer on the third carrier board and covering the second chip; and
the HBM structure is welded on and electrically connected to a surface of the second carrier board of the first package structure that is exposed by the first carrier board and faces the first carrier board.

8. The semiconductor package according to claim 7, further comprising:
a first heat dissipation layer on a surface of the second package structure and a surface of the HBM structure facing away from the second carrier board of the first package structure, wherein the first heat dissipation layer is configured to conduct heat generated by the second package structure and the HBM structure to the outside.

9. The semiconductor package according to claim 1, wherein the HBM structure comprises a plurality of memory chips stacked on top of one another along a longitudinal direction, and the plurality of memory chips are electrically connected to each other.

10. The semiconductor package according to claim 9, wherein each of the plurality of memory chips comprises a Dynamic Random Access Memory (DRAM).

11. The semiconductor package according to claim 3, further comprising:
a first welding interconnection structure between the first package structure and the second surface of the first carrier board, configured to weld the first package structure on the second surface of the first carrier board and electrically connect the first package structure to the first carrier board; and
a second welding interconnection structure between the second package structure and the third surface of the first carrier board, configured to weld the second package structure on the third surface of the first carrier board and electrically connect the second package structure to the first carrier board.

12. The semiconductor package according to claim 3, wherein the first surface is a side surface of the first carrier board, the second surface is a back surface of the first carrier board, and the third surface is a front surface of the first carrier board.

13. A package method, comprising:
providing a first carrier board having a plurality of first assembly surfaces and a first surface, wherein signal exchange ports are provided on the first surface;
providing a plurality of package structures, each corresponding to one of the plurality of first assembly surfaces;
welding the plurality of package structures on their corresponding first assembly surfaces of the first carrier board, respectively, and electrically connecting the plurality of package structures to the first carrier board, wherein an end of at least one of the plurality of package structures is exposed and faces away from the first surface of the first carrier board;
providing a High Bandwidth Memory (HBM) structure; and
welding the HBM structure on and electrically connecting the HBM structure to a surface of the end of the at least one of the plurality of package structures that faces the first carrier board.

14. The package method according to claim 13, wherein each of the plurality of package structures comprises a chip or a chip package structure.

15. The package method according to claim 14, wherein:
each of the plurality of first assembly surfaces comprises a second surface and a third surface opposing the second surface;
providing the plurality of package structures comprises: providing a first package structure and a second package structure; and
welding the plurality of package structures on their corresponding first assembly surfaces comprises: welding the first package structure on the second surface; welding the second package structure on the third surface; and electrically connecting the first package structure and the second package structure to the first carrier board.

16. The package method according to claim 15, wherein:
after welding the first package structure and the second package structure, a first end of the first package structure and a second end of the second package structure are exposed and face away from the first surface, and the first carrier board, the first end of the first package structure, and the second end of the second package structure enclose a reserved space; and
welding the HBM structure comprises: welding the HBM structure within the reserved space on and electrically connecting the HBM structure to a surface of the first end of the first package structure and a surface of the second end of the second package structure that face the first carrier board, respectively.

17. The package method according to claim 16, wherein:
providing the first package structure and the second package structure comprises, for each:
providing a second carrier board having a second assembly surface;
welding a first chip on and electrically connecting the first chip to the second assembly surface of the second carrier board; and
forming a first package molding layer on the second carrier board to cover the first chip; and
welding the HBM structure comprises: welding the HBM structure on and electrically connecting the HBM structure to a surface of the second carrier board of the first package structure and a surface of the second carrier board of the second package structure that are exposed by the first carrier board and face the first carrier board, respectively.

18. The package method according to claim 15, wherein:
after welding the first package structure and the second package structure, the first carrier board exposes a first end of the first package structure facing away from the first surface; and
welding the HBM structure comprises: welding the HBM structure on and electrically connecting the HBM structure to an exposed surface of the first end of the first package structure that faces the first carrier board.

19. The package method according to claim 18, wherein:
providing the first package structure comprises:
providing a second carrier board having a second assembly surface;
welding a first chip on and electrically connecting the first chip to the second assembly surface of the second carrier board; and
forming a first package molding layer on the second carrier board to cover the first chip;
providing the second package structure comprises:
providing a third carrier board having a third assembly surface;
welding a second chip on and electrically connecting the second chip to the third assembly surface of the third carrier board; and
forming a second package molding layer on the third carrier board to cover the second chip; and
welding the HBM structure comprises: welding the HBM structure on and electrically connecting the HBM structure to the exposed surface of the second carrier board of the first package structure that faces the first carrier board.

20. The package method according to claim 19, further comprising:
forming a first heat dissipation layer on a surface of the second package structure and a surface of the HBM structure facing away from the second carrier board of the first package structure, wherein the first heat dissipation layer is configured to conduct heat generated by the second package structure and the HBM structure to the outside.
